(19) United States
(12) Patent Application Publication
(10) Pub. No.: US 2013/0128436 A1
(43) Pub. Date: May 23, 2013

(54) SERVER WITH BACK PLANE MODULE

(71) Applicant: YAO-TING CHANG, Tu-Cheng (TW)

(72) Inventor: YAO-TING CHANG, Tu-Cheng (TW)

(73) Assignee: HON HAI PRECISION INDUSTRY CO., LTD., Tu-Cheng (TW)

(21) Appl. No.: 13/326,257

(22) Filed: Dec. 14, 2011

(30) Foreign Application Priority Data
Nov. 18, 2011 (TW) 100142459

(51) Int. Cl. H05K 7/02

(52) U.S. Cl. 361/679.02

(57) ABSTRACT

A server includes a chassis, a back plane module mounted in the chassis, and a number of electronic component mounted to the back plane module. The back plane module includes a first back plane adjacent to a top plate of the chassis, a second back plane adjacent to a bottom plate of the chassis, and a cable connecting the first and second back planes. The second back plane is offset from the first back plane so as to form a passage for a cooling airflow between the first and second back planes.

### BACKGROUND

1. Technical Field

The present disclosure relates to a server with a back plane module.

2. Description of Related Art

A server includes a chassis, a back plane mounted in a middle of the chassis, and a plurality of electronic components, such as power supplies, fans, and expansion cards, coupled to opposite side surfaces of the back plane. The back plane defines a plurality of vents for air ventilation through the back plane. However, the greater the number of vents, the less space of the back plane available for circuit(s), and the weaker the back plane.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric view of an exemplary embodiment of a server.

FIG. 2 is a sectional view taken along line II-II of FIG. 1.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

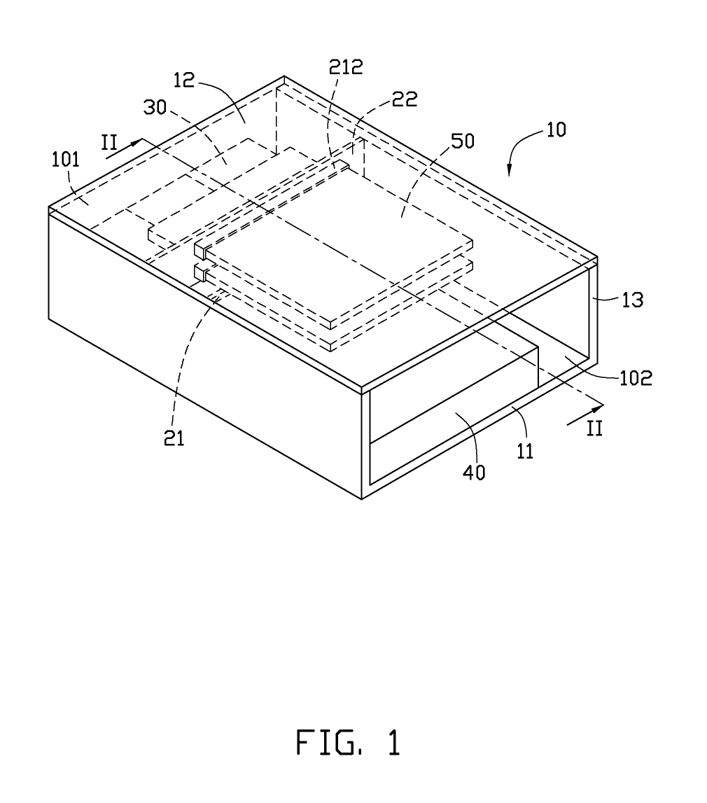

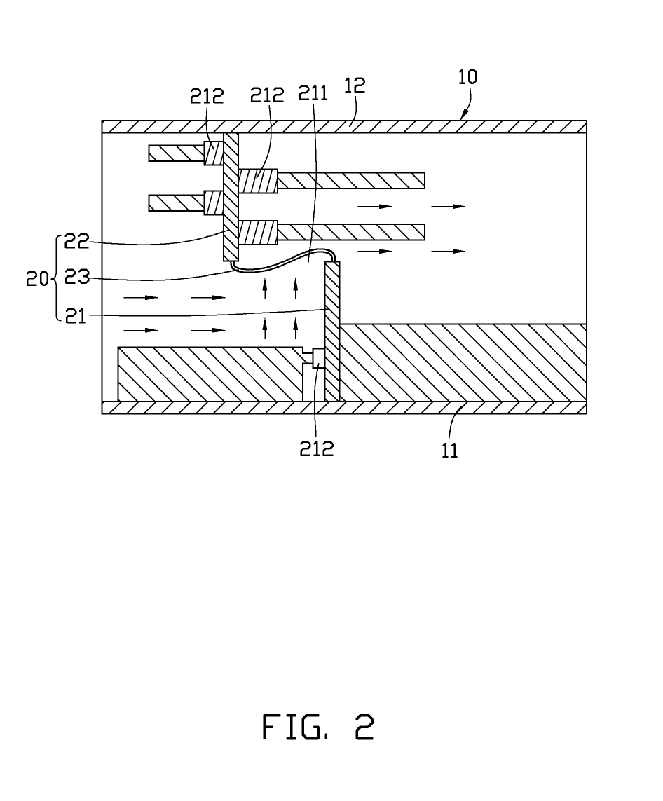

Referring to FIGS. 1 and 2, an exemplary embodiment of a server includes a chassis 10, a back plane module 20, and a plurality of electronic components, such as power supplies 30, data storage devices 40, and expansion cards 50, coupled to the back plane module 20.

The chassis 10 includes a bottom plate 11, two sidewalls 13 respectively extending up from opposite sides of the bottom plate 11, and a top plate 12 connected between the tops of the sidewalls 13 opposite to the bottom plate 11. The bottom plate 11, sidewalls 13, and top plate 12 cooperatively bound a receiving space for receiving the back plane module 20 and the electronic components. A front opening 101 and a rear opening 102 are defined in opposite ends of the chassis 10, communicating with the receiving space. Air enters the receiving space of the chassis 10 through the front opening 101 for cooling the back plane module 20 and the electronic components, and is expelled out of the chassis 10 through the rear opening 102.

The back plane module 20 includes a first back plane 21, a second back plane 22, and a cable 23 connected between the first and second back planes 21 and 22, for data transfer between the first and second back planes 21 and 22. The first and second back planes 21 and 22 are perpendicularly fixed to the sidewalls 13, and respectively adjacent to the bottom plate 11 and the top plate 12. Therefore, the first back plane 21 is apart from the top plate 12, and the second back plane 22 is apart from the bottom plate 11. The first and second back planes 21 and 22 are parallel to each other. The second back plane 22 is perpendicularly offset from the first back plane 21. Therefore, a passage 211 is formed between the first and second back planes 21 and 22.

A plurality of connectors 212 is arranged on opposite sides of each of the first and second back planes 21 and 22, to connect the electronic components. The height of each of the first and second back planes 21 and 22 is less than a distance between the top plate 12 and the bottom plate 11. In one embodiment, the sum of the heights of the first and second back planes 21 and 22 is substantially equal to the distance between the top plate 12 and the bottom plate 11.

In use, when air flows to the back plane module 20 from the front opening 101, the air is guided to flow through the passage 211, and thence to the rear opening 102. Vents in the first or second back plane 21 and 22 do not need to be defined because of the air flowing through the passage 211, thereby allowing complete structural strength for the first and second back planes 21 and 22, and enough space for arranging or laying out circuit(s).

It is to be understood, however, that even though numerous characteristics and advantages of the embodiment have been set forth in the foregoing description, together with details of the structure and function of the embodiment, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A server comprising:
a chassis comprising a bottom plate and a top plate parallel to the bottom plate;
a first back plane received in the chassis and depending from the bottom plate, the first back plane apart from the top plate;
a second back plane received in the chassis and depending from the top plate, the second back plane apart from the bottom plate;
a plurality of electronic components respectively coupled to the first and second back planes; and
a cable electrically connected between the first and second back planes for data transfer between the first and second back planes;
wherein the first and second back planes are parallel to each other, and the second back plane offsets from the first back plane along a direction perpendicular to the first back plane; a height of each of the first and second back planes is less than a distance between the bottom and top plates.

2. The server of claim 1, wherein each of the first and second back planes comprises a plurality of connectors for connecting the electronic components, and the connectors are arranged in opposite side surfaces of the first and second back planes.
